(19) United States
(12) Patent Application Publication
(10) Pub. No.: US 2006/0043500 A1
(43) Pub. Date: Mar. 2, 2006

(54) Transistor structure with stress modification and capacitive reduction feature in a channel direction and method thereof

(76) Inventors: Jian Chen, Austin, TX (US); Michael A. Mendicino, Austin, TX (US); Vance H. Adams, Austin, TX (US); Choh-Fei Yeap, San Diego, CA (US); Venkat R. Kolagunta, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/925,057

(22) Filed: Aug. 24, 2004

(51) Int. Cl. H01L 29/76; H01L 29/94

(52) U.S. Cl. 257/401; 257/369; 257/288; 257/368; 257/382

(57) ABSTRACT

A transistor comprises an active region having a periphery with opposing sides and a source and a drain positioned within the active region. A gate overlies a channel area of the active region, the channel region separating the source and drain. The transistor further includes at least one stress modifying feature extending from an edge of the active region on at least one of a source side or a drain side and toward the channel area but not entering the channel area. The at least one stress modifying feature includes a dielectric.

### CROSS-REFERENCE TO RELATED APPLICATIONS

This application is related to an application entitled “Transistor Structure With Stress Modification and Capacitive Reduction Feature in a Width Direction and Method Thereof”, Chen et al., Attorney Docket SC13329TP, filed concurrently herewith and incorporated herein in its entirety by reference.

### BACKGROUND

The present disclosures relate generally to semiconductor devices, and more particularly, to a transistor structure and method of making a transistor structure with stress modification and capacitive reduction features in a channel direction.

Current techniques for creating compressive stress for PFET devices include using silicon germanium (SiGe) epi in source/drain (S/D) regions of a PFET transistor and to provide an improvement in the PFET performance. However, such techniques are very complicated. Furthermore, there exist a large number of integration challenges for implementation of such techniques, for example, integration challenges associated with SiGe epi, silicide, S/D extension profile control, etc.

Accordingly, it would be desirable to provide an improved transistor structure and method of making the same for overcoming the problems in the art.

### SUMMARY

According to one embodiment, a transistor comprises an active region having a periphery with opposing sides and a source and a drain positioned within the active region. A gate overlies a channel area of the active region, the channel region separating the source and drain. The transistor further includes at least one stress modifying feature extending from an edge of the active region on at least one of a source side or a drain side and toward the channel area but not entering the channel area. The at least one stress modifying feature includes a dielectric.

### BRIEF DESCRIPTION OF THE DRAWINGS

The embodiments of the present disclosure are illustrated by way of example and not limited by the accompanying figures, in which like references indicate similar elements, and in which:

FIG. 1 is a top view of a CMOS transistor illustrating a channel direction and width direction as is known in the art;

FIG. 2 is a table view of stress response sensitivity characteristics for various channel orientations and device types;

FIG. 3 is a top view of a typical CMOS transistor structure known in the art;

FIG. 4 is a top view of a CMOS transistor structure with a stress modification feature in a channel direction according to one embodiment of the present disclosure;

FIG. 5 is a characteristic curve representation of a performance metric versus distance D of a stress modification feature to a channel of an active region of a transistor according to one embodiment of the present disclosure;

FIG. 6 is a characteristic curve representation of a performance metric versus a ratio of total stress modification feature widths, W_{F-TOTAL}, to overall width W_{OVERALL} of a transistor having a number of stress modification features according to one embodiment of the present disclosure;

FIG. 7 is a top view of a CMOS transistor structure with a stress modification feature in a channel direction including a stress modifying liner according to another embodiment of the present disclosure;

FIG. 8 is a top view of a CMOS transistor structure with a stress modification feature in a channel direction according to another embodiment of the present disclosure;

FIG. 9 is a top view of a CMOS transistor structure with a stress modification feature in a channel direction including a stress modifying liner according to another embodiment of the present disclosure;

FIG. 10 is a top view of a CMOS transistor structure with a stress modification feature in a channel direction according to yet another embodiment of the present disclosure;

FIG. 11 is a top view of a CMOS transistor building block structure with a stress modification feature in a channel direction according to another embodiment of the present disclosure;

FIG. 12 is a top view of a CMOS transistor structure fabricated using the building block structure of FIG. 11 having a stress modification feature in a channel direction according to another embodiment of the present disclosure;

FIG. 13 is a top view of a CMOS transistor building block structure with a stress modification feature in a channel direction according to another embodiment of the present disclosure;

FIG. 14 is a top view of a CMOS transistor building block structure with a stress modification feature in a channel direction according to yet another embodiment of the present disclosure; and

FIG. 15 is a top plan view of an integrated circuit including transistor structures according to another embodiment of the present disclosure.

The use of the same reference symbols in different drawings indicates similar or identical items. Skilled artisans will also appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

The embodiments of the present disclosure provide for enabling a favorable stress for PFET performance enhancement. In silicon-on-insulator (SOI) technology, the silicon film is very thin. As a result, the silicon film is typically very sensitive to stress effect, for example, such as trench induced stress. According to an embodiment of the present disclosure, a method of making a PFET transistor includes forming a trench much closer to the transistor gate and thus creating compressive stress that is favorable for improved PFET performance. Such a method is much easier to implement compared with a SiGe epi process. In addition, the method described herein is also applicable to both SOI and bulk silicon and to NFET performance enhancement.

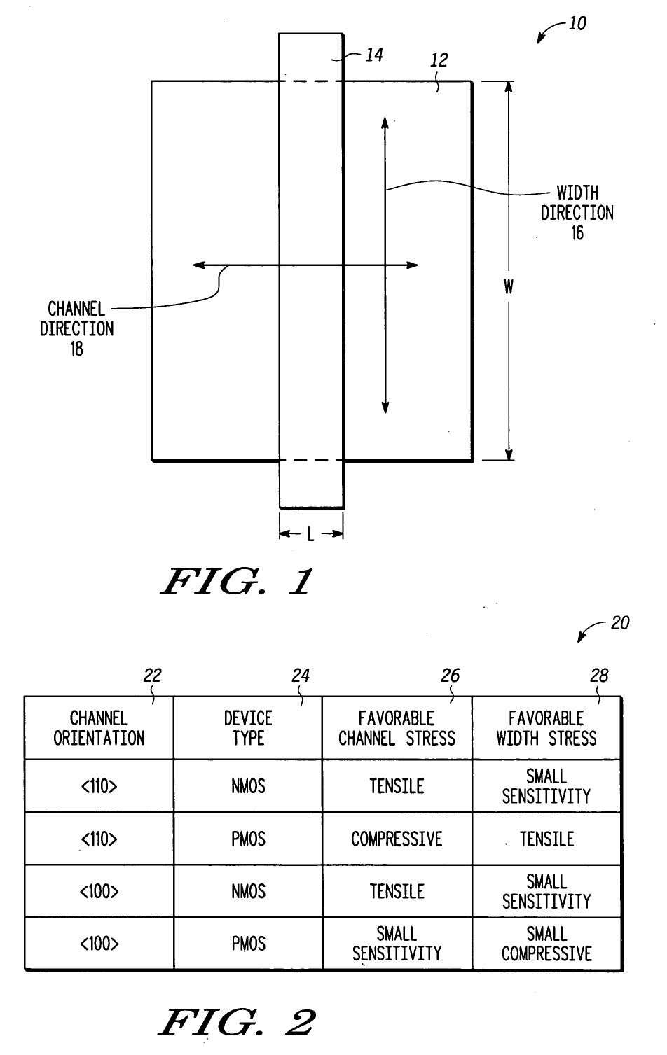

FIG. 1 is a top view of a CMOS transistor 10 illustrating a channel direction and width direction as is known in the art. In particular CMOS transistor 10 includes an active region 12 and a gate electrode 14, with an underlying gate dielectric (not shown). Active region 12 is characterized by a width dimension W extending in a width direction, the width direction being indicated by reference numeral 16. In addition, active region 12 comprises any suitable semiconductor material. Gate electrode 14 is characterized by a length dimension L extending in a channel direction, the channel direction being indicated by reference numeral 18.

FIG. 2 is a table view of stress response sensitivity characteristics for various channel orientations and device types. The table is based on short channel device behavior. In particular, the table 20 of FIG. 2 includes columns of channel orientation 22, device type 24, favorable channel stress 26, and favorable width stress 28. For a channel orientation of <110>, an NMOS device performs best under tensile stress in the channel direction. In addition, for a channel orientation of <110>, the NMOS device performance has a relatively small sensitivity to stress in width direction. For a channel orientation of <1 10>, a PMOS device performs best under compressive stress in the channel direction and under tensile stress in width direction. For a channel orientation of <100>, an NMOS device performs best under tensile stress in the channel direction and has a relatively small sensitivity to stress in width direction. Lastly, for a channel orientation of <100>, a PMOS device performance demonstrates a relatively small sensitivity to stress in the channel direction, but does respond favorably to compressive stress in the width direction.

FIG. 3 is a top view of a typical CMOS transistor structure known in the art. In particular CMOS transistor 30 includes an active region 32 and a gate electrode 34, with an underlying gate dielectric (not shown). Active region 32 is characterized by a width dimension W extending in a width direction. In addition, active region 32 comprises any suitable semiconductor material. Gate electrode 34 is characterized by a length dimension L extending in a channel direction. Transistor 30 also includes contacts 36 for making contact with respective source and drain regions, 33 and 35, respectively. With respect to the CMOS transistor 30, the same could be further optimized from a performance stand point.

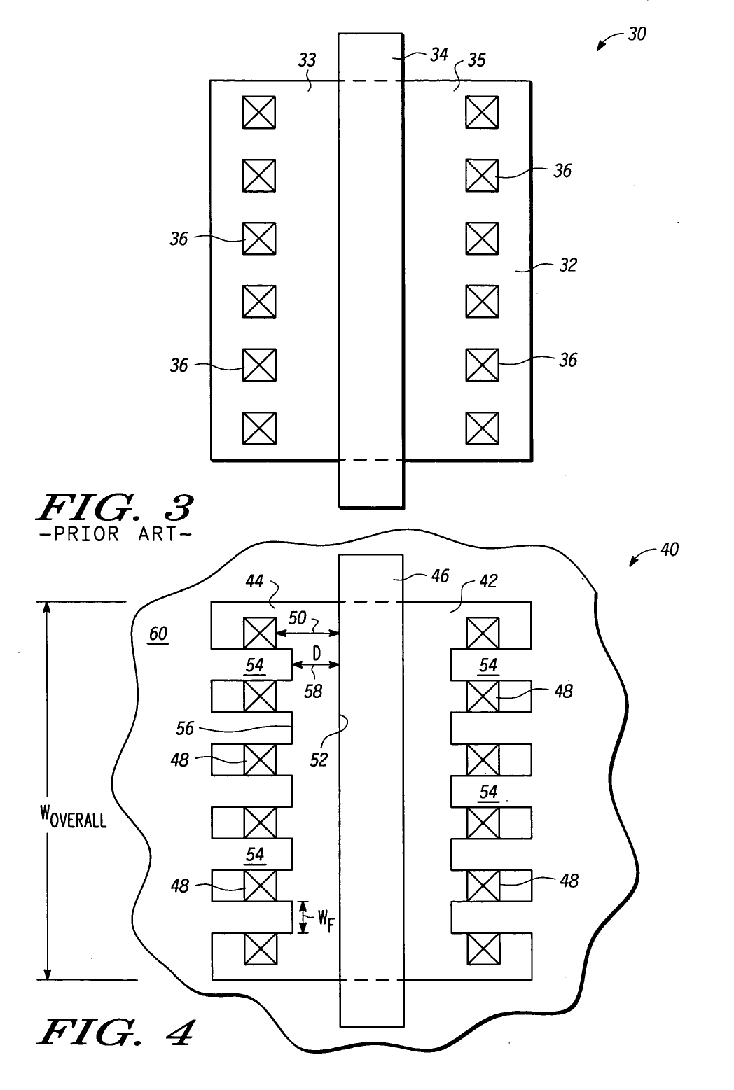

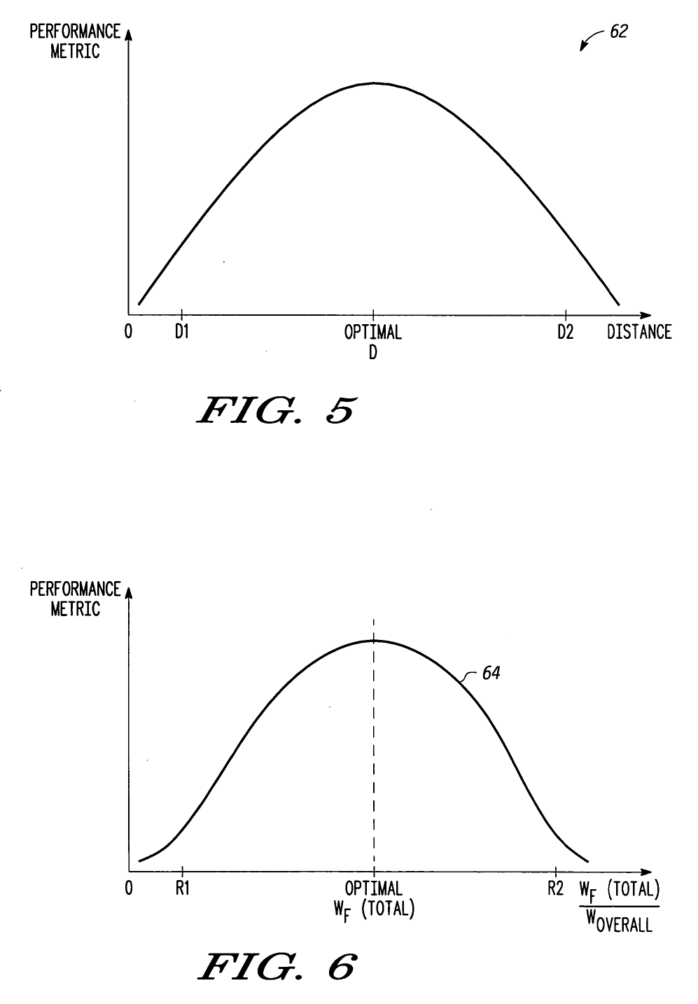

FIG. 4 is a top view of a CMOS transistor structure 40 with a stress modification feature in a channel direction according to one embodiment of the present disclosure. In particular, CMOS transistor 40 comprises an active region that includes source region 42 and drain region 44, and further comprises a gate electrode 46, with an underlying gate dielectric (not shown). In addition, the active region can comprise any suitable semiconductor material. Gate electrode 46 is characterized by a length dimension L extending in a channel direction. Transistor 40 also includes contacts 48 for making contact with respective source and drain regions, 42 and 44 of the active region. Contacts 48 are spaced by a distance represented by reference numeral 50 from an edge 52 of the gate electrode 46. With respect to the CMOS transistor 40, the same has been optimized from a performance stand point as further discussed herein.

Optimization of CMOS transistor 40 includes the addition of stress modification features 54, wherein the features provide a modification of stresses in the channel direction as will be discussed further herein. The features 54 have an edge 56 disposed a distance 58 from a nearest edge 52 of the gate electrode 46. In general, distance 58 is less than or equal to the distance 50, as will be further discussed herein. In addition, features 54 are also characterized by a feature width W_{F}, as will also be further discussed herein. Furthermore, the active region of transistor 40 is characterized by a width dimension W_{OVERALL}. In one embodiment, a dielectric 60 surrounds transistor 40 and fills stress modification features 54. Dielectric 60 can include, for example, a field oxide or other dielectric material suitable for the requirements of a particular transistor application.

According to one embodiment, a transistor comprises an active region having a periphery with opposing sides and a source and a drain positioned within the active region. A gate overlies a channel area of the active region, the channel region separating the source and drain. The transistor further includes at least one stress modifying feature extending from an edge of the active region on at least one of a source side or a drain side and toward the channel area but not entering the channel area. The at least one stress modifying feature includes a dielectric. In one embodiment, the at least one stress modifying feature extends from both the source side and the drain side of the active region.

The transistor further includes a plurality of contacts. Each of the at least one stress modifying feature is positioned substantially between a predetermined different two of the plurality of contacts. Furthermore, the at least one stress modifying feature is positioned in closer proximity to the channel region than the plurality of contacts.

In another embodiment, the transistor further comprises at least two stress modifying liners, a first stress modifying liner surrounding at least a portion of the periphery of the active region and a second stress modifying liner surrounding at least a portion of a surface of the at least one stress modifying feature. The first stress modifying liner and second stress modifying liner configures for providing different stress effects on the active region.

Still further, in another embodiment, the transistor channel region is oriented in a <110> channel orientation and the transistor comprises a PMOS transistor. The stress modifying feature comprises a material that exerts a compressive stress on the channel region in a channel direction.

In yet another embodiment, the transistor channel region has a channel orientation of <110> or <100> and the transistor comprises an NMOS transistor. The stress modifying feature comprises a material that exerts a tensile stress on the channel region in a channel direction. Furthermore, the stress modifying feature comprises a region previously occupied by the active region.

FIG. 5 is a characteristic curve representation 62 of a performance metric versus distance D of a stress modification feature to a channel of an active region of a transistor according to one embodiment of the present disclosure. In particular, the performance metric axis extends from a low performance to a high performance. The distance axis extends from a small distance D1 to a larger distance D2, including an optimal distance D_{OPTIMAL}. At distances greater than the optimal distance, the transistor performance suffers from a loss of positive response due to stress. For distances less than the optimal distance, the transistor performance suffers due to current crowding effects.

FIG. 6 is a characteristic curve representation 64 of a performance metric versus a ratio of total stress modification feature widths, W_{F-TOTAL}, to overall width W_{OVERALL} of a transistor having a number of stress modification features according to one embodiment of the present disclosure. In particular, the performance metric axis extends from a low performance to a high performance. The width axis extends from a small ratio R1 of total stress modification feature widths, W_{F-TOTAL}, to overall width W_{OVERALL} to a larger ratio R2 of total stress modification feature widths, W_{F-TOTAL}, to overall width W_{OVERALL}, including an optimal ratio, W_{F-TOTAL(OPTIMAL)}. At widths greater than the optimal ratio, the transistor performance suffers due to current crowding effects. For distances less than the optimal distance, the transistor performance suffers from a loss of positive response due to stress. Accordingly, there exists an optimal width and distance for achieving an optimal performance.

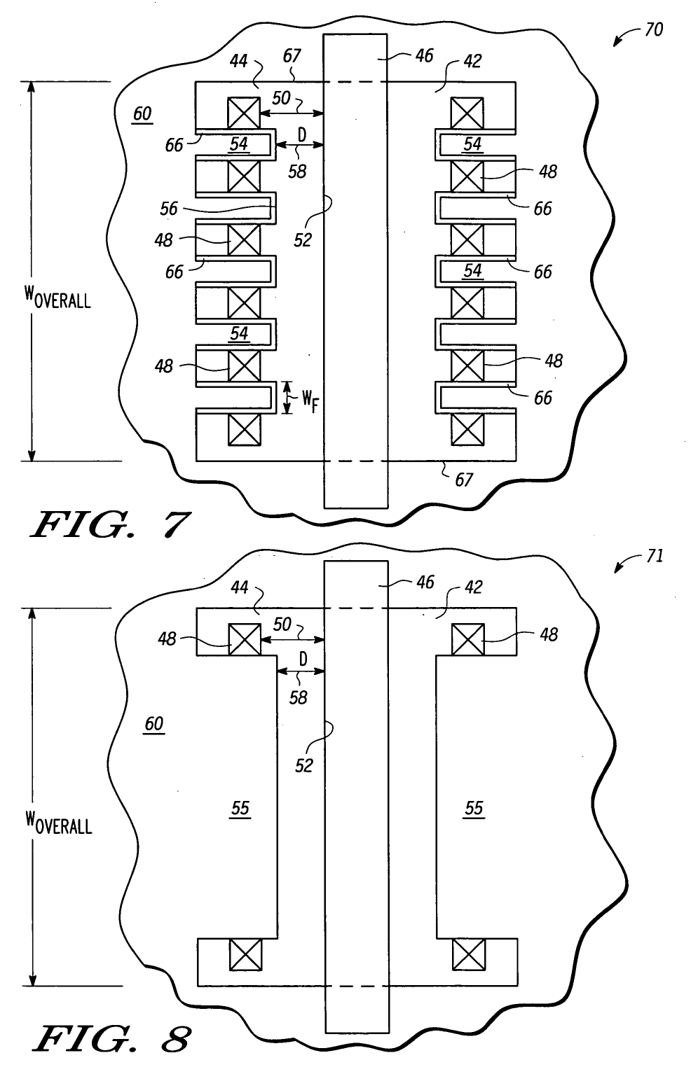

FIG. 7 is a top view of a CMOS transistor structure 70 with a stress modification feature in a channel direction including a stress modifying liner(s) according to another embodiment of the present disclosure. CMOS transistor structure 70 is similar to that shown and described herein above with respect to FIG. 4, with the following differences. CMOS transistor structure 70 includes stress modifying liners 66 and 67. In one embodiment, stress modifying liner 66 includes a thick oxide liner, for example, on the order of 100-400 angstroms thick. In addition, stress modifying liner 67 includes a thin oxide liner, for example, on the order of 0-100 angstroms thick.

Accordingly, the transistor 70 includes at least two stress modifying liners. A first stress modifying liner surrounds at least a portion of the periphery of the active region and a second stress modifying liner surrounds at least a portion of the at least one stress modifying feature. Furthermore, the first stress modifying liner and second stress modifying liner are configured for providing different stress effects on the active region.

FIG. 8 is a top view of a CMOS transistor structure 71 with a stress modification feature in a channel direction according to another embodiment of the present disclosure. CMOS transistor structure 71 is similar to that shown and described herein above with respect to FIG. 4, with the following differences. On each of the source and drain sides of CMOS transistor structure 71 there is a stress modification feature 55 having a width W_{F} that extends between two outermost contacts 48 in a width direction. Accordingly, each of the source and drain regions have only two contacts.

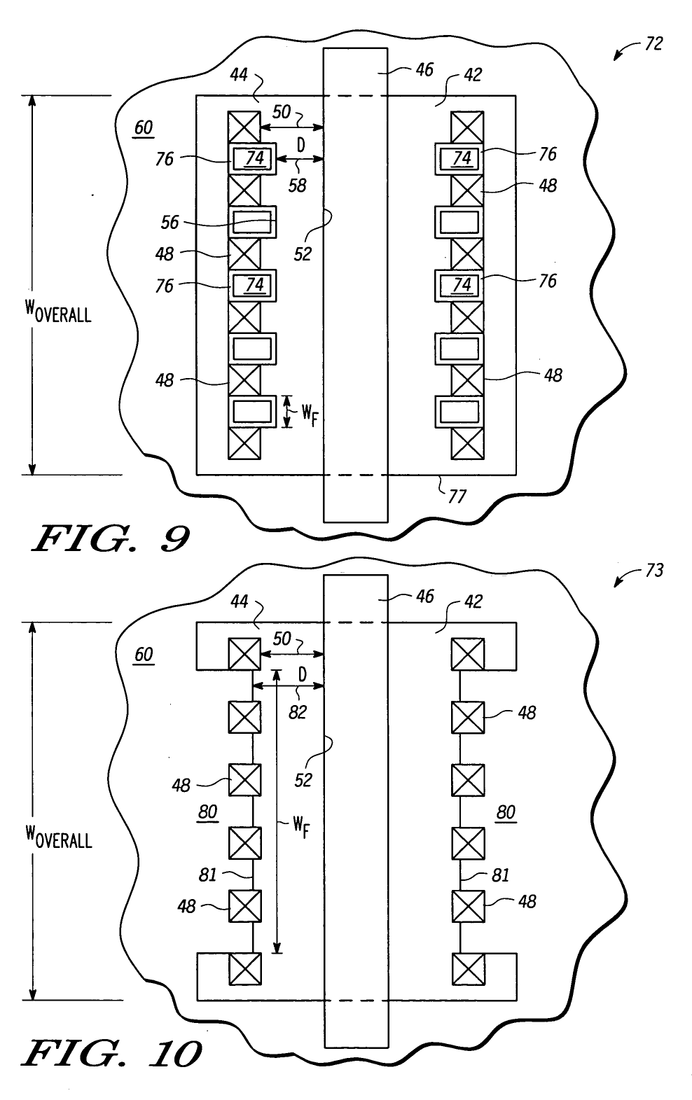

FIG. 9 is a top view of a CMOS transistor structure 72 with a stress modification feature in a channel direction including a stress modifying liner according to another embodiment of the present disclosure. CMOS transistor structure 72 is similar to that shown and described herein above with respect to FIG. 7, with the following differences. CMOS transistor structure 72 includes stress modifying features 74 that are fully enclosed by respective active source and drain regions (42, 44). In addition, the stress modifying features 74 include stress modifying liner 76. In one embodiment, stress modifying liner 76 includes a thick oxide liner, for example, on the order of 100-400 angstroms thick. In addition, transistor structure 72 may further comprise stress modifying liner 77. In one embodiment, stress modifying liner 77 includes a thin oxide liner, for example, on the order of 0-100 angstroms thick.

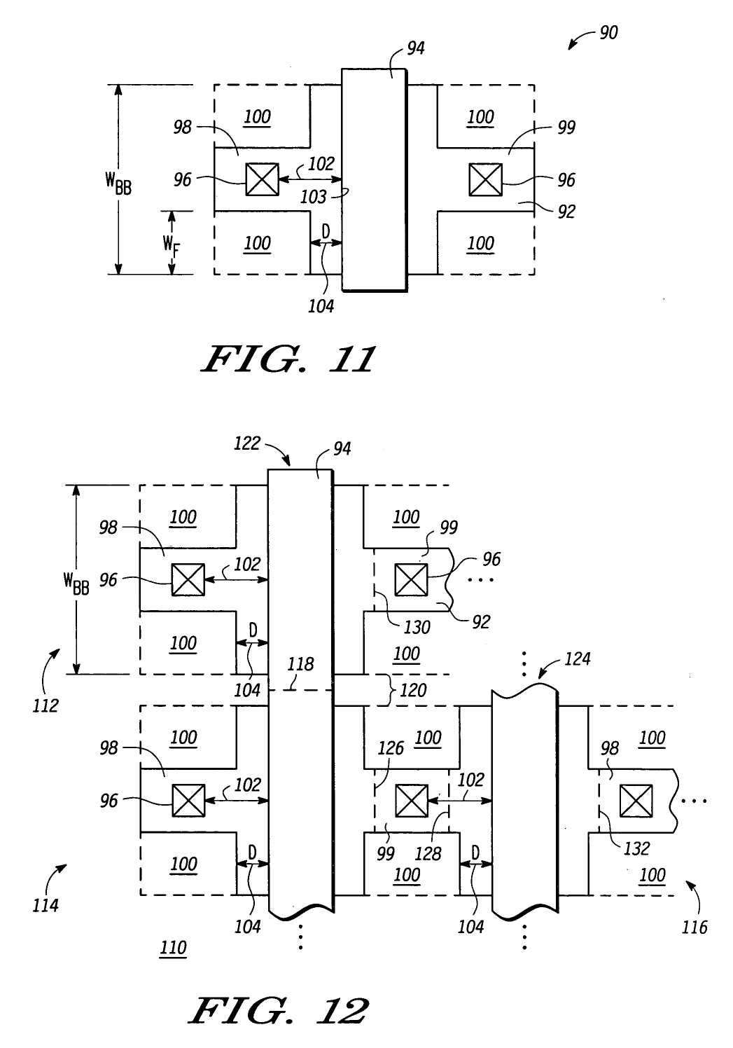

FIG. 10 is a top view of a CMOS transistor structure 73 with a stress modification feature in a channel direction according to yet another embodiment of the present disclosure. CMOS transistor structure 73 is similar to that shown and described herein above with respect to FIG. 8, with the following differences. CMOS transistor structure 73 includes stress modifying features 80 that are within respective active source and drain regions (42, 44). The features 80 have an edge 81 disposed a distance 82 from a nearest edge 52 of the gate electrode 46. In general, distance 82 is greater than the distance 50. In addition, features 80 are also characterized by a feature width W_{F}. Furthermore, the active region of transistor 73 is characterized by a width dimension W_{OVERALL}. In one embodiment, a dielectric 60 surrounds transistor 73 and fills stress modification features 80. Dielectric 60 can include, for example, a field oxide or other dielectric material suitable for the requirements of a particular transistor application. Furthermore, some of contacts 48 (i.e., the ones that reside in-between the outermost contacts) overly feature 80.

According to another embodiment, a transistor comprises an active region having a periphery with opposing sides; a source and a drain positioned within the active region; a gate overlying a channel area of the active region, the channel region separating the source and drain; and at least one stress modifying feature enclosed within either the source or the drain and positioned substantially between a predetermined two of a plurality of contacts to the source or drain, respectively, the at least one stress modifying feature comprising a dielectric region.

With respect to the transistor of the immediately preceding paragraph, in one embodiment, the at least one stress modifying feature is within both the source and the drain within the active region. In another embodiment, the transistor further comprises a plurality of contacts, wherein each of the at least one stress modifying feature is positioned substantially between a predetermined different two of the plurality of contacts. In one example, the at least one stress modifying feature is positioned in closer proximity to the channel region than the plurality of contacts.

According to yet another embodiment, a transistor comprises an active region having a periphery with opposing sides; a source positioned within the active region; a drain positioned within the active region; a gate overlying a channel area of the active region, the channel region separating the source and drain; and at least one stress modifying feature positioned within at least one of the source or the drain, the at least one stress modifying feature overlying a plurality of contacts to the source or drain, respectively, and comprising a region filled with a dielectric. In one example, the at least one stress modifying feature extends to an edge of the active region. In another example, the at least one stress modifying feature is within both the source and the drain within the active region.

FIG. 11 is a top view of a CMOS transistor building block structure 90 with a stress modification feature in a channel direction according to another embodiment of the present disclosure. Transistor building block structure 90 includes an active semiconductor region, generally indicated by reference numeral 92. Overlying the active semiconductor region 92 is a gate electrode 94, with an underlying gate dielectric (not shown). Active semiconductor region 92 comprises any suitable semiconductor material for a given transistor application. Gate electrode 94 is characterized by a length dimension extending in the channel direction. Transistor building block 90 further includes contacts 96 for making contact with respective source and drain regions, 98 and 99, of active region 92. Contacts 96 are spaced by a distance represented by reference numeral 102 from an edge 103 of the gate electrode 94.

With respect to the building block 90, the same has been optimized from a performance point of view similarly as discussed herein with respect to the embodiment of FIG. 4. For example, features 100 are similar to features 54. In addition, distances 102 and 104 are similar to distances 50 and 58, respectively. However, active region 92 of building block 90 is characterized by a building block width dimension W_{BB} and extending in the width direction, whereas the embodiment of FIG. 4 is characterized by an overall width W_{OVERALL}.

FIG. 12 is a top view of a CMOS transistor structure 110 fabricated using the building block structure of FIG. 11 having a stress modification feature in a channel direction according to another embodiment of the present disclosure. CMOS transistor structure 110 includes a number of building blocks 112, 114, 116, and so on, wherein the total number of building blocks is determined by the requirements of a given transistor application. In one embodiment, each of building blocks 112, 114, and 116 comprise the building block structure 90 of FIG. 11. In addition, each of the building blocks 112, 114, and 116 have a width, W_{BB}. As shown, building block 112 is physically joined to building block 114 at a portion of the gate electrode of each, further as illustrated by the dashed line 118. Building block 112 and 114 share a common gate electrode, generally indicated by reference numeral 122. Furthermore, the contacts 96 located in the source regions 98 or 99 of building blocks 112 and 114 are strapped together at backend interconnect circuitry (not shown) for a particular transistor structure application. Likewise, the contacts 96 located in the drain region 99 or 98 of building blocks 112 and 114 are also strapped together by the backend interconnect circuitry.

Similarly, building block 114 is physically joined to building block 116 at a portion of active region of each, where the active regions overlap in a region between the dashed lines 126 and 128. Building blocks 114 and 116 share a common source/drain region 99.

Furthermore, building block 112 may be physically joined to another building block (not shown) at a portion of the active region of each, where the active regions would overlap in a region to the right of dashed line 130. Still further, building block 116 may be physically joined to other building blocks (not shown) similarly as described with respect to the coupling of blocks 112, 114, and 116. With respect to block 116, reference numeral 124 refers to a common gate electrode that block 116 can share with another block (not shown). Yet still further, building block 116 may be physically joined to another building block (not shown) at a portion of the active region of each, where the active regions would overlap in a region to the right of dashed line 132. Building blocks 112 and 116 and their corresponding other building blocks (not shown) would share a respective common source/drain region 99 and 98, respectively.

As discussed, transistor structure 110 can further include additional building blocks, as illustrated by the series of dots “ . . . ”. Building blocks combined in the width direction that share common gate electrodes as in gate electrode 118 of building blocks 112 and 114 will have the source and drain contacts, respectively, strapped together by the backend interconnect circuitry as previously described. Lastly, the overall width dimension of transistor structure 110 (W_{OVERALL}) is the sum of the widths of individual blocks and the spacings between individual blocks in the width direction.

According to one embodiment, the transistor further comprises at least two predetermined transistor building blocks each having a source, a drain and a gate. Each of the at least two predetermined transistor building blocks have a width and a side perimeter substantially traversing the width with a first portion of the side perimeter in closer proximity to the channel than a second portion of the side perimeter to form a first stress modifying feature adjacent the first portion of the side perimeter. In addition, the at least two predetermined transistor building blocks having their gates physically joined. Furthermore, in another embodiment, a plurality of transistor building blocks that are physically connected to form multiple gates with multiple stress modifying features.

In another embodiment, the at least two predetermined building blocks form two physically adjacent stress modifying features when the at least two predetermined building blocks are physically connected. In yet another transistor embodiment, the channel region has a <110> channel orientation and the transistor is a PMOS transistor, wherein the stress modifying feature comprises a material that exerts a compressive stress on the channel region in a channel direction. In still another embodiment, the channel region has a channel orientation of <110> or <100> and the transistor is an NMOS transistor, wherein the stress modifying feature comprises a material that exerts a tensile stress on the channel region in a channel direction.

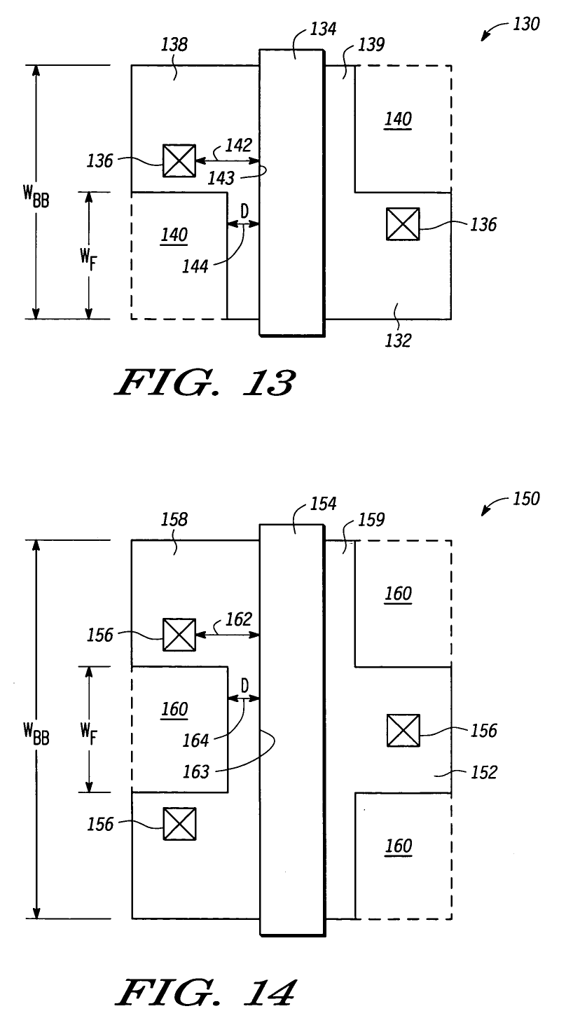

FIG. 13 is a top view of a CMOS transistor building block structure 130 with a stress modification feature in a channel direction according to another embodiment of the present disclosure. Transistor building block structure 130 includes an active semiconductor region, generally indicated by reference numeral 132. Overlying the active semiconductor region 132 is a gate electrode 134, with an underlying gate dielectric (not shown). Active semiconductor region 132 comprises any suitable semiconductor material for a given transistor application. Gate electrode 134 is characterized by a length dimension extending in the channel direction. Transistor building block 130 further includes contacts 136 for making contact with respective source and drain regions, 138 and 139, of active region 132. Contacts 136 are spaced by a distance represented by reference numeral 142 from an edge 143 of the gate electrode 134.

With respect to the building block 130, the same has been optimized from a performance point of view similarly as discussed herein with respect to the embodiment of FIG. 4. For example, features 140 are similar to features 54. In addition, distances 142 and 144 are similar to distances 50 and 58, respectively. However, active region 132 of building block 130 is characterized by a building block width dimension W_{BB} and extending in the width direction, whereas the embodiment of FIG. 4 is characterized by an overall width W_{OVERALL}. In addition, the locations of the stress modification features with respect to the active region of FIG. 13 are different from those shown in FIG. 11.

FIG. 14 is a top view of a CMOS transistor building block structure 150 with a stress modification feature in a channel direction according to yet another embodiment of the present disclosure. Transistor building block structure 150 includes an active semiconductor region, generally indicated by reference numeral 152. Overlying the active semiconductor region 152 is a gate electrode 154, with an underlying gate dielectric (not shown). Active semiconductor region 152 comprises any suitable semiconductor material for a given transistor application. Gate electrode 154 is characterized by a length dimension extending in the channel direction. Transistor building block 150 further includes contacts 156 for making contact with respective source and drain regions, 158 and 159, of active region 152. Contacts 156 are spaced by a distance represented by reference numeral 162 from an edge 163 of the gate electrode 154.

With respect to the building block 150, the same has been optimized from a performance point of view similarly as discussed herein with respect to the embodiment of FIG. 4. For example, features 160 are similar to features 54. In addition, distances 162 and 164 are similar to distances 50 and 58, respectively. However, active region 152 of building block 150 is characterized by a building block width dimension W_{BB} and extending in the width direction, whereas the embodiment of FIG. 4 is characterized by an overall width W_{OVERALL}. In addition, the locations of the stress modification features with respect to the active region of FIG. 14 are different from those shown in FIG. 11. Furthermore, building blocks of FIGS. 11, 13 and 14 can be combined in any suitable manner to form a structure similar to that as shown and described herein with respect to FIG. 12.

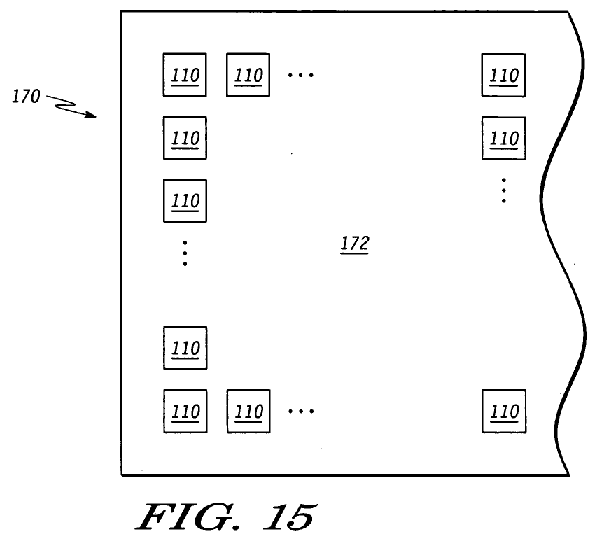

FIG. 15 is a top plan view of an integrated circuit die 170 having a portion 172 that includes transistor structures 110 according to the embodiments of the present disclosure. In one embodiment, the transistor structures 110 include non-memory devices. A substantial number of devices within 172 employ transistor structures 110. Accordingly, the integrated circuit comprises a plurality of transistors, each of the plurality of transistors having a structure of the transistor embodiments as described herein. In addition, the structure of the transistor is implemented in at least a majority of transistors of a predetermined conductivity type used to implement a non-memory function in an integrated circuit die.

According to one embodiment, a method of forming a transistor comprises providing an active region having a periphery with opposing sides and positioning a source and drain within the active region. A gate is formed overlying a channel area of the active region, the channel region separating the source and drain. The method further includes forming at least one stress modifying feature extending from an edge of the active region on at least one of a source side or a drain side and toward the channel area, the at least one stress modifying feature comprising a dielectric.

In one embodiment, the method further comprises forming at least two stress modifying liners, a first stress modifying liner surrounding at least a portion of the periphery of the active region and a second stress modifying liner surrounding at least a portion of the at least one stress modifying feature, the first stress modifying liner and second stress modifying liner having different stress effects on the active region. Furthermore, forming the at least one stress modifying feature is accomplished by removing a region previously occupied by the active region and filling the region with the dielectric.

In another embodiment, the method further comprises providing at least two predetermined transistor building blocks each having a source, a drain and a gate. Each of the at least two predetermined transistor building blocks have a width and a side perimeter substantially traversing the width with a first portion of the side perimeter in closer proximity to the channel than a second portion of the side perimeter to form a first stress modifying feature adjacent the first portion of the side perimeter. The method further includes physically joining the at least two predetermined transistor building blocks by connecting the gate of each of the at least two transistor building blocks.

In another embodiment, the method further includes orienting the channel direction in either a <100> crystal orientation or a <110> crystal orientation and implementing the transistor as an N-channel MOS transistor. A tensile stress is exerted on the active region with the dielectric. In yet another embodiment, the method further includes orienting the channel direction in a <110> crystal orientation and implementing the transistor as a P-channel transistor. A compressive stress is exerted on the active region with the dielectric.

In yet another embodiment, a method of forming a transistor includes providing an active region having a periphery with opposing sides, positioning a source and a drain within the active region, forming a gate overlying a channel area of the active region, the channel region separating the source and drain, and forming at least one stress modifying feature enclosed within either the source or the drain and positioned substantially between any two of a plurality of contacts to the source or drain, respectively, the at least one stress modifying feature comprising a dielectric region. The method can further include forming at least two stress modifying liners, a first stress modifying liner surrounding at least a portion of the periphery of the active region and a second stress modifying liner surrounding at least a portion of the at least one stress modifying feature, the first stress modifying liner and second stress modifying liner having different stress effects on the active region.

In another embodiment, a method of forming a transistor comprises providing an active region having a periphery with opposing sides; positioning a source within the active region; positioning a drain within the active region; forming a gate overlying a channel area of the active region, the channel region separating the source and drain; forming at least one stress modifying feature by removing material comprising at least one of the source or the drain, the at least one stress modifying feature overlying a plurality of contacts to the source or drain, respectively, and comprising a region previously occupied by the active region; and filling the at least one stress modifying feature with a dielectric. The method can further include forming at least two stress modifying liners, a first stress modifying liner surrounding at least a portion of the periphery of the active region and a second stress modifying liner surrounding at least a portion of the at least one stress modifying feature, the first stress modifying liner and second stress modifying liner having different stress effects on the active region.

Accordingly, a method has been disclosed for optimizing an SOI PFET layout and for forming a trench closer to a channel region to create favorable compressive stress. In one embodiment, the forming of a trench closer to the channel region is achieved through one or more of patterning an elongated trench along the gate, creating a series of contact-like small trench holes along the gate, or creating a jog in the active region for a similar purpose. Furthermore, the method uses SOI specific stress effects to achieve compressive stress for a PFET device and structure. Such a method is much easier to implement on SOI in comparison with a SiGe epi approach used on bulk silicon.

According to another embodiment of the present disclosure, a method for enhancing transistor performance includes applying different oxidations to different regions of active Si isolation to customize stresses for obtaining an enhanced transistor performance. Process steps include, for example, performing multi-step isolation that includes multiple oxidations to create differential stresses. Key components include, for example, an active device region with multiple liner thicknesses. Furthermore, the present embodiment exploits a directional mobility response to stress without the use of exotic materials, exotic processing, or new tools.

In the foregoing specification, the disclosure has been described with reference to various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments. For example, the present embodiments can apply to semiconductor device technologies where carrier mobility is crucial to the device performance.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A transistor comprising:
an active region having a periphery with opposing sides;
a source positioned within the active region;
a drain positioned within the active region;
a gate overlying a channel area of the active region, the channel region separating the source and drain; and
at least one stress modifying feature extending from an edge of the active region on at least one of a source side or a drain side and toward the channel area but not entering the channel area, the at least one stress modifying feature comprising a dielectric.

2. The transistor of claim 1 wherein the at least one stress modifying feature extends from both the source side and the drain side of the active region.

3. The transistor of claim 1 further comprising a plurality of contacts, each of the at least one stress modifying feature positioned substantially between a predetermined different two of the plurality of contacts.

4. The transistor of claim 3 wherein the at least one stress modifying feature is positioned in closer proximity to the channel region than the plurality of contacts.

5. The transistor of claim 1 further comprising:
at least two stress modifying liners, a first stress modifying liner surrounding at least a portion of the periphery of the active region and a second stress modifying liner surrounding at least a portion of a surface of the at least one stress modifying feature, the first stress modifying liner and second stress modifying liner having different stress effects on the active region.

6. The transistor of claim 1 wherein the channel region is oriented in a <110> channel orientation and the transistor is a PMOS transistor.

7. The transistor of claim 6 wherein the stress modifying feature comprises a material that exerts a compressive stress on the channel region in a channel direction.

8. The transistor of claim 1 wherein the channel region has a channel orientation of <110> or <100> and the transistor is an NMOS transistor.

9. The transistor of claim 8 wherein the stress modifying feature comprises a material that exerts a tensile stress on the channel region in a channel direction.

10. The transistor of claim 1 wherein the stress modifying feature comprises a region previously occupied by the active region.

11. The transistor of claim 1, further comprising at least two predetermined transistor building blocks each having a source, a drain and a gate, each of the at least two predetermined transistor building blocks having a width and a side perimeter substantially traversing the width with a first portion of the side perimeter in closer proximity to the channel than a second portion of the side perimeter to form a first stress modifying feature adjacent the first portion of the side perimeter, the at least two predetermined transistor building blocks having their gates physically joined.

12. The transistor of claim 11 further comprising a plurality of transistor building blocks that are physically connected to form multiple gates with multiple stress modifying features.

13. The transistor of claim 12 wherein the at least two predetermined building blocks form two physically adjacent stress modifying features when the at least two predetermined building blocks are physically connected.

14. The transistor of claim 12 further comprising:
at least two stress modifying liners, a first stress modifying liner surrounding at least a portion of the periphery of the active region and a second stress modifying liner surrounding at least a portion of the at least one stress modifying feature, the first stress modifying liner and second stress modifying liner having different stress effects on the active region.

15. The transistor of claim 12 wherein the channel region has a <110> channel orientation and the transistor is a PMOS transistor.

16. The transistor of claim 15 wherein the stress modifying feature comprises a material that exerts a compressive stress on the channel region in a channel direction.

17. The transistor of claim 12 wherein the channel region has a channel orientation of <110> or <100> and the transistor is an NMOS transistor.

18. The transistor of claim 17 wherein the stress modifying feature comprises a material that exerts a tensile stress on the channel region in a channel direction.

19. The transistor of claim 1 further comprising a plurality of transistors, each of the plurality of transistors having a structure of the transistor of claim 1, the structure of the transistor of claim 1 being implemented in at least a majority of transistors of a predetermined conductivity type used to implement a non-memory function in an integrated circuit die.

20. A transistor comprising:
an active region having a periphery with opposing sides;
a source positioned within the active region;
a drain positioned within the active region;
a gate overlying a channel area of the active region, the channel region separating the source and drain; and
at least one stress modifying feature enclosed within either the source or the drain and positioned substantially between a predetermined two of a plurality of contacts to the source or drain, respectively, the at least one stress modifying feature comprising a dielectric region.

21. The transistor of claim 20 wherein the at least one stress modifying feature is within both the source and the drain within the active region.

22. The transistor of claim 20 further comprising a plurality of contacts, each of the at least one stress modifying feature positioned substantially between a predetermined different two of the plurality of contacts.

23. The transistor of claim 22 wherein the at least one stress modifying feature is positioned in closer proximity to the channel region than the plurality of contacts.

24. The transistor of claim 20 further comprising:
at least two stress modifying liners, a first stress modifying liner surrounding at least a portion of the periphery of the active region and a second stress modifying liner surrounding at least a portion of the at least one stress modifying feature, the first stress modifying liner and second stress modifying liner having different stress effects on the active region.

25. The transistor of claim 20 wherein the channel region has a channel orientation of <110> and the transistor is a PMOS transistor.

26. The transistor of claim 25 wherein the at least one stress modifying feature comprises a material that exerts a compressive stress on the channel region in a channel direction.

27. The transistor of claim 20 wherein the channel region has a channel orientation of <110> or <100> and the transistor is an NMOS transistor.

28. The transistor of claim 27 wherein the at least one stress modifying feature comprises a material that exerts a tensile stress on the channel region in a channel direction.

29. A transistor comprising:
an active region having a periphery with opposing sides;
a source positioned within the active region;
a drain positioned within the active region;
a gate overlying a channel area of the active region, the channel region separating the source and drain; and
at least one stress modifying feature positioned within at least one of the source or the drain, the at least one stress modifying feature overlying a plurality of contacts to the source or drain, respectively, and comprising a region filled with a dielectric.

30. The transistor of claim 29 wherein the at least one stress modifying feature extends to an edge of the active region.

31. The transistor of claim 29 wherein the at least one stress modifying feature is within both the source and the drain within the active region.

32. The transistor of claim 29 further comprising:
at least two stress modifying liners, a first stress modifying liner surrounding at least a portion of the periphery of the active region and a second stress modifying liner surrounding at least a portion of the at least one stress modifying feature, the first stress modifying liner and second stress modifying liner having different stress effects on the active region.

33. The transistor of claim 29 wherein the channel region has a <110> channel orientation and the transistor is a PMOS transistor.

34. The transistor of claim 33 wherein the at least one stress modifying feature comprises a material that exerts a compressive stress on the channel region in a channel direction.

35. The transistor of claim 29 wherein the channel region has a channel orientation of <110> or <100> and the transistor is an NMOS transistor.

36. The transistor of claim 35 wherein the at least one stress modifying feature comprises a material that exerts a tensile stress on the channel region in a channel direction.

37. A method of forming a transistor comprising:
providing an active region having a periphery with opposing sides;
positioning a source within the active region;
positioning a drain within the active region;
forming a gate overlying a channel area of the active region, the channel region separating the source and drain;
forming at least one stress modifying feature extending from an edge of the active region on at least one of a source side or a drain side and toward the channel area, the at least one stress modifying feature comprising a dielectric.

38. The method of claim 37 further comprising:
forming at least two stress modifying liners, a first stress modifying liner surrounding at least a portion of the periphery of the active region and a second stress modifying liner surrounding at least a portion of the at least one stress modifying feature, the first stress modifying liner and second stress modifying liner having different stress effects on the active region.

39. The method of claim 37 further comprising:
forming the at least one stress-modifying feature by removing a region previously occupied by the active region and filling the region with the dielectric.

40. The method of claim 37 further comprising:
providing at least two predetermined transistor building blocks each having a source, a drain and a gate, each of the at least two predetermined transistor building blocks having a width and a side perimeter substantially traversing the width with a first portion of the side perimeter in closer proximity to the channel than a second portion of the side perimeter to form a first stress modifying feature adjacent the first portion of the side perimeter; and
physically joining the at least two predetermined transistor building blocks by connecting the gate of each of the at least two transistor building blocks.

41. The method of claim 37 further comprising:
orienting the channel direction in either a <100> crystal orientation or a <110> crystal orientation and implementing the transistor as an N-channel MOS transistor.

42. The method of claim 37 further comprising:
exerting a tensile stress on the active region with the dielectric.

43. The method of claim 37 further comprising:
orienting the channel direction in a <110> crystal orientation and implementing the transistor as a P-channel transistor.

44. The method of claim 37 further comprising:
exerting a compressive stress on the active region with the dielectric.

45. A method of forming a transistor comprising:
providing an active region having a periphery with opposing sides;
positioning a source within the active region;
positioning a drain within the active region;
forming a gate overlying a channel area of the active region, the channel region separating the source and drain;
forming at least one stress modifying feature enclosed within either the source or the drain and positioned substantially between any two of a plurality of contacts to the source or drain, respectively, the at least one stress modifying feature comprising a dielectric region.

46. The method of claim 45 further comprising:
forming at least two stress modifying liners, a first stress modifying liner surrounding at least a portion of the periphery of the active region and a second stress modifying liner surrounding at least a portion of the at least one stress modifying feature, the first stress modifying liner and second stress modifying liner having different stress effects on the active region.

47. The method of claim 45 further comprising:
forming the at least one stress modifying feature by removing a region previously occupied by the active region and filling the region with the dielectric.

48. The method of claim 45 further comprising:
providing at least two predetermined transistor building blocks each having a source, a drain and a gate, each of the at least two predetermined transistor building blocks having a width and a side perimeter substantially traversing the width with a first portion of the side perimeter in closer proximity to the channel than a second portion of the side perimeter to form a first stress modifying feature adjacent the first portion of the side perimeter; and
physically joining the at least two predetermined transistor building blocks by connecting the gate of each of the at least two transistor building blocks.

49. A method of forming a transistor comprising:
providing an active region having a periphery with opposing sides;
positioning a source within the active region;
positioning a drain within the active region;
forming a gate overlying a channel area of the active region, the channel region separating the source and drain;
forming at least one stress modifying feature by removing material comprising at least one of the source or the drain, the at least one stress modifying feature overlying a plurality of contacts to the source or drain, respectively, and comprising a region previously occupied by the active region; and
filling the at least one stress modifying feature with a dielectric.

50. The method of claim 49 further comprising:
forming at least two stress modifying liners, a first stress modifying liner surrounding at least a portion of the periphery of the active region and a second stress modifying liner surrounding at least a portion of the at least one stress modifying feature, the first stress modifying liner and second stress modifying liner having different stress effects on the active region

51. The method of claim 49 further comprising:
forming the at least one stress modifying feature by removing a region previously occupied by the active region and filling the region with the dielectric.

52. The method of claim 49 further comprising:
providing at least two predetermined transistor building blocks each having a source, a drain and a gate, each of the at least two predetermined transistor building blocks having a width and a side perimeter substantially traversing the width with a first portion of the side perimeter in closer proximity to the channel than a second portion of the side perimeter to form a first stress modifying feature adjacent the first portion of the side perimeter; and
physically joining the at least two predetermined transistor building blocks by connecting the gate of each of the at least two transistor building blocks.
